(19) United States
(12) Patent Application Publication
(10) Pub. No.: US 2009/0168557 A1
(43) Pub. Date: Jul. 2, 2009

(54) Ultra wide voltage range register file circuit using programmable triple stacking

(76) Inventors: Amit Agarwal, Hillsboro, OR (US); Steven K. Hsu, Lake Oswego, OR (US); Ram K. Krishnamurthy, Portland, OR (US)

Correspondence Address: Caven & Aghevli LLC;c/o CPA Global, P.O. BOX 52050, MINNEAPOLIS, MN, 55402, US

(21) Appl. No.: 12/006,276

(22) Filed: Dec. 31, 2007

(51) Int. Cl. G11C 5/14

(52) U.S. Cl. 365/189.11

(57) ABSTRACT

Methods and apparatus relating to expanding the operational voltage range of data storage circuits are described. In an embodiment, low voltage data storage circuit operation is improved by driving a transistor with a control word line programmable circuit. Other embodiments are also described.

### FIELD

The subject matter described herein generally relates to digital circuits. In one embodiment, some of the techniques described herein may be utilized to expand the operational voltage range of data storage circuits.

### BACKGROUND

High performance multiprocessor design may aggressively scale down the supply voltage of cores based on workload to achieve power efficiency. This may require register files to have high performance at nominal-Vcc and to be functional at ultra low supply voltages. However, since register file designs may be based on wide OR dynamic logic circuits, which may be used in local (LBL) or global (GBL) bit-lines, the leakage current present in the NMOS pull-down paths may be large which may result in leakage induced read instability. This effect may amplify with technology and voltage scaling.

### BRIEF DESCRIPTION OF THE DRAWINGS

The detailed description is provided with reference to the accompanying figures. In the figures, the left-most digit(s) of a reference number identifies the figure in which the reference number first appears. The use of the same reference numbers in different figures indicates similar or identical items.

FIG. 1 illustrates a circuit diagram, according to some embodiments.

FIG. 2 illustrates a diagram of a logic used to drive transistors, according to an embodiment.

FIG. 3 is a flow diagram of a method to drive a transistor, according to an embodiment.

FIG. 4 illustrates sample voltage droop, in accordance with some embodiments.

FIG. 5 illustrates a computing system, according to an embodiment.

### DETAILED DESCRIPTION

In the following description, numerous specific details are set forth in order to provide a thorough understanding of various embodiments. However, various embodiments of the invention may be practiced without the specific details. In other instances, well-known methods, procedures, components, and circuits have not been described in detail so as not to obscure the particular embodiments of the invention. Further, various aspects of embodiments of the invention may be performed using various means, such as integrated semiconductor circuits (“hardware”), computer-readable instructions organized into one or more programs (“software”), or some combination of hardware and software. For the purposes of this disclosure reference to “logic” shall mean either hardware, software, or some combination thereof.

Some of the embodiments discussed herein may expand the operational voltage range of data storage circuits such as memory bit cells. In an embodiment, the bit cells designs discussed herein may be used for register files of processors. Generally, a register file refers to an array of registers accessed by components of a processor. In one embodiment, a Programmable leakage tolerant technique Triple Stacking (PTS) may provide bit cells that operate at ultra low supply voltages, while maintaining performance at high supply voltages. For example, an embodiment may allow for bit cells to operate between about 200 mV and as high as 1.2V or more.

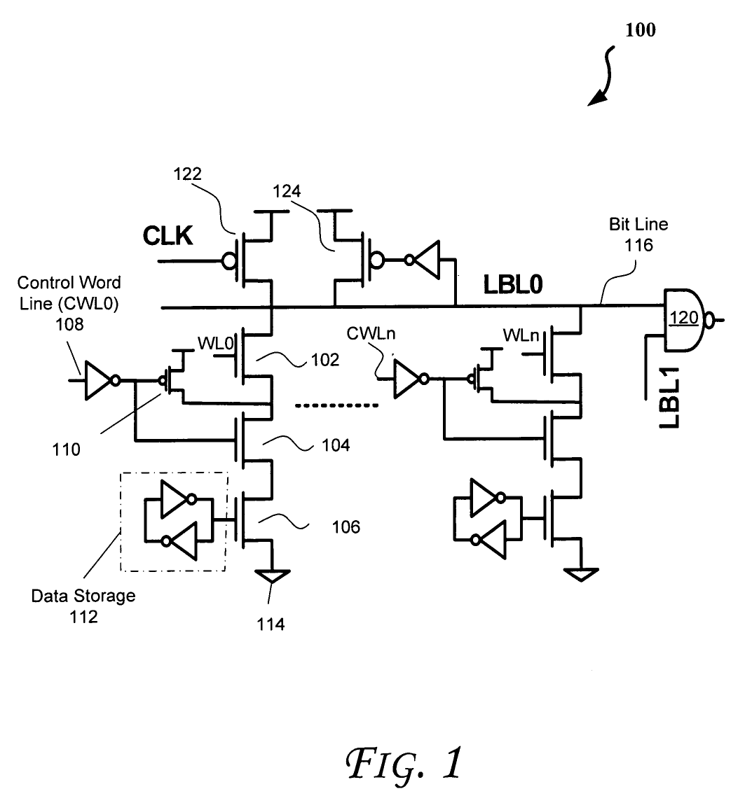

FIG. 1 illustrates portions of an integrated circuit (IC) 100 that may be used in an ultra-wide voltage range register file, in accordance with some embodiments. In various embodiments, the circuit 100 may be used as domino read local bitline at ultra-low voltages, such as discussed further herein with reference to FIGS. 1-4, for example.

As shown in FIG. 1, the circuit 100 may include a first transistor 102, a second transistor 104, and a third transistor 106 coupled in series to a bit line 116. For example, the first transistor may be an access transistor, the second transistor may be an intermediate transistor, and the third transistor may be a pass transistor. The second transistor 104 may be coupled to a control word line 108 (e.g., through an inverter such as shown in FIG. 1). As shown in FIG. 1, a fourth transistor 110 may also be coupled to the word line 108 (e.g., through an inverter such as shown in FIG. 1). The fourth transistor 110 (which may be minimum sized PMOS in an embodiment) may also be coupled to an intermediate stack node and a supply voltage, e.g., to pull the intermediate stack node to Vcc, for example. This may reduce the pull-down leakage in PTS LBL exponentially (e.g., negative Vgs), resulting in conventional sized kepper PMOS transistor 124 to be strong enough to compensate the pull-down NMOS leakage at low supply voltages.

Further, the third transistor 106 may be coupled to a data storage cell 112 (formed by two cross-coupled inverters such as shown in FIG. 1) and a fixed voltage (which may be ground, positive, or negative depending on the implementation) such as ground 114. Even though specific types of the transistors are shown in FIG. 1 (e.g., NMOS (N-Channel Metal Oxide Semiconductor) and PMOS (P-Channel Metal Oxide Semiconductor) transistors), the type of transistors may be changed depending on the implementation.

As shown in FIG. 1, transistors 102, 104, and 106 may be stacked to provide a triple stacked programmable memory bit cell capable of operating under a wide range of supply voltages. Further, only two branches of a local bit line (LBL0) are shown in FIG. 1. However, additional branches may be present (as indicated by WL0 through WLn or CWL0 through CWLn labeling). Also, the output of bit line 116 (LBL0) may be combined with outputs of other bit lines (e.g., LBL1 via an NAND gate 120 such as shown in FIG. 1). Moreover, bit line 116 may be coupled to two pull-up PMOS transistors such as transistor 122 (which is driven by a clock signal) and transistor 124 (which is coupled to the bit line 116 via an inverter).

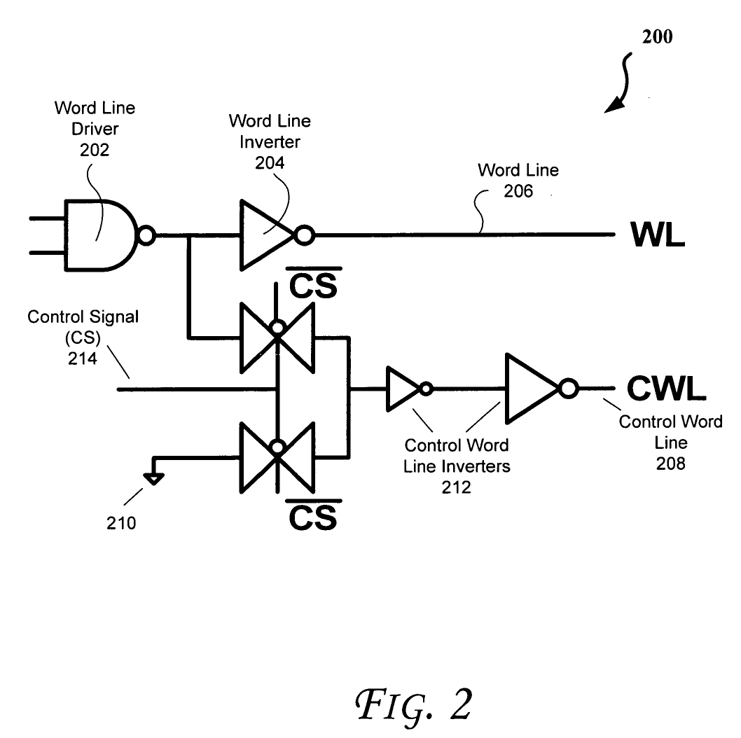

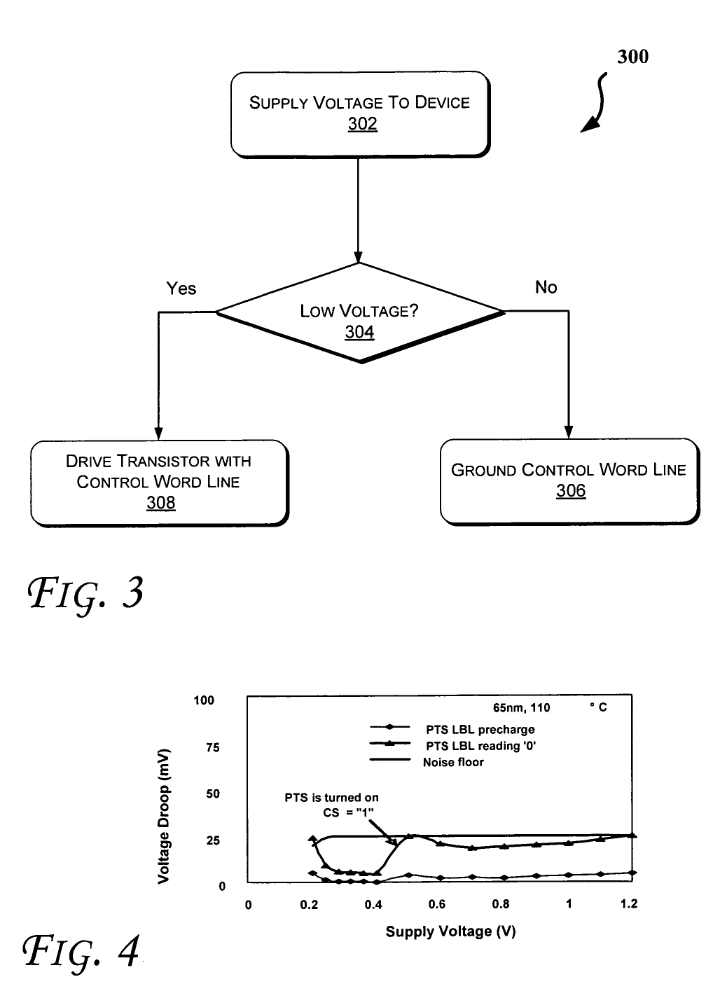

FIG. 2 is an illustration of a diagram of a logic 200 used to drive transistors, according to an embodiment. In some embodiments, the logic 200 may be used to drive the first transistor 102 of FIG. 1 (e.g., via the word line (WL) signal) and/or the second transistor 104 of FIG. 1 (e.g., via the control word line (CWL) signal). In an embodiment, the logic 200 may couple the control word line 208 to a fixed voltage (which may be ground, positive, or negative depending on the implementation) such as ground 210 for operation at high voltages, while logic 200 may drive the second transistor 104 of FIG. 1 (e.g., based on read word line (WL)) during low voltage operations, such a discussed further herein, e.g., with reference to FIG. 3.

As shown in FIG. 2, the logic 200 may include a word line driver 202 (driven by read decoder which decodes the read address, for example) which is coupled to a word line inverter 204, e.g., to reduce load on the word line driver 202. The word line driver 202 may generate a signal that drives a word line 206 (e.g., after passing through the inverter 204). The output of the driver 202 may be used in combination with a control signal (CS) 214 (and complementary versions of CS as shown in FIG. 2) to generate a control word line (CWL) signal 208. In an embodiment, the control signal 214 (and its complementary versions) may be a global control signal, e.g., provided to more than one memory bit cell. Accordingly, logic 200 may determine if the control word line 208 should be driven or coupled to a fixed voltage, e.g., grounded (210), depending on the operating voltage levels. In some embodiments, the control word line 208 may be locally buffered using one or more control word line inverters 212, e.g., to reduce the load on the word line driver 202 and/or reduce the energy overhead at high supply voltage operation.

FIG. 3 is a flow diagram of a method 300 to drive a transistor, according to an embodiment. In one embodiment, the method 300 may be used to drive a transistor with a control word line at low voltages or to couple the control word line to a fixed voltage (which may be ground, positive, or negative depending on the implementation) such as ground at high voltages. As shown in FIG. 3, at operation 302, voltage may be supplied to a device such as a memory cell (e.g., within a register file). At an operation 304, it may be determined whether the device is operating at a low voltage range (such as discussed with reference to FIG. 2). At an operation 306, if the device is not operating in a low voltage range, the control word line may be coupled to a fixed voltage such as ground (e.g., keeping the second transistor 104 of FIG. 1 on). Otherwise, at an operation 308, if the device is operating at a low voltage range, the control word line may be coupled to drive a transistor in the triple stacked configuration (e.g., coupled to drive the second transistor 104 of FIG. 1).

FIG. 4 illustrates sample voltage droop, in accordance with some embodiments. More particularly, FIG. 4 shows sample voltage droop at the dynamic node of LBL during pre-charge and evaluation (reading 0) at 110° C. and at worst case corner (fast NMOS and weak PMOS) for supply voltage range between 0.2V-1.2V. PTS is enabled for supply voltages below 0.5V. FIG. 4 shows that PTS LBL meets the noise criteria at all operating voltages down to 0.2V. Further, at 1.2V the conventional register file operates at 6.4 GHz while PTS operates at 6.1 GHz (4.5% delay overhead). At low supply voltage range (0.2V-0.5V) conventional register file is not functional. At Vcc=0.2V PTS operates at 4.4 MHz. PTS shows negligible power overhead at high supply voltage range (0.5V-1.2V), consuming 47 mW of power at 1.2V. Power reduces considerably with supply voltage scaling reaching 10 μW at 0.2V.

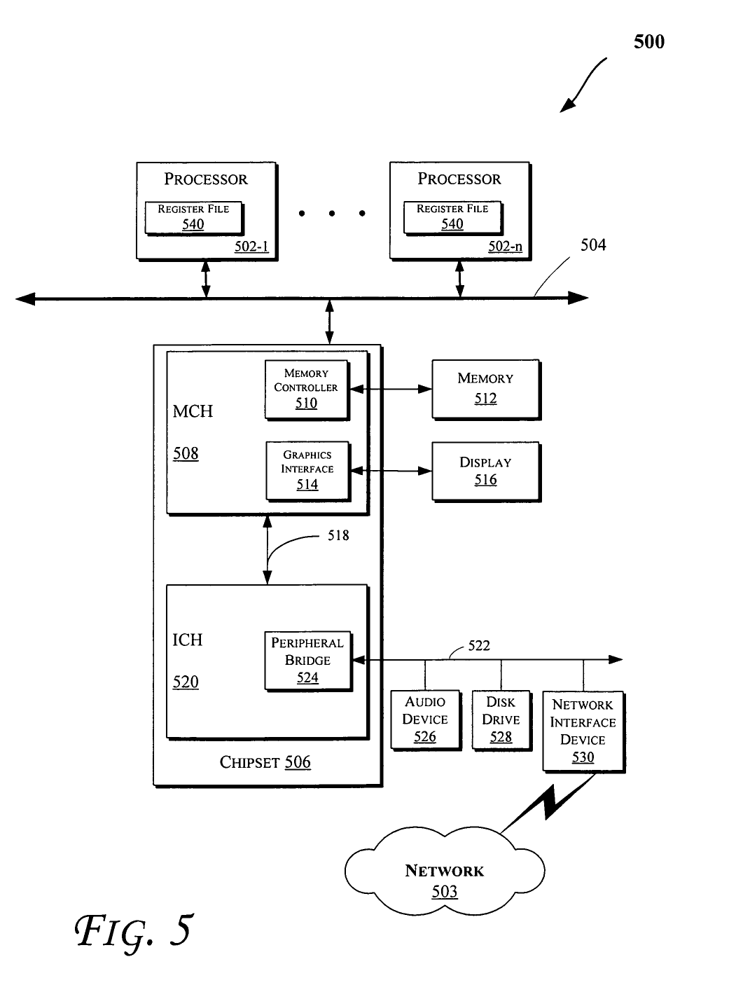

FIG. 5 illustrates a block diagram of a computing system 500 in accordance with an embodiment of the invention. The computing system 500 may include one or more central processing unit(s) (CPUs) 502 or processors that communicate via an interconnection network (or bus) 504. The processors 502 may include a general purpose processor, a network processor (that processes data communicated over a computer network 503), or other types of a processor (including a reduced instruction set computer (RISC) processor or a complex instruction set computer (CISC)). Moreover, the processors 502 may have a single or multiple core design. The processors 502 with a multiple core design may integrate different types of processor cores on the same integrated circuit (IC) die. Also, the processors 502 with a multiple core design may be implemented as symmetrical or asymmetrical multiprocessors. In an embodiment, one or more of the components discussed with reference to FIG. 5 (such as the processors 502) may include a register file 540 that may utilize bit cells such as those discussed with reference to FIGS. 1-4.

A chipset 506 may also communicate with the interconnection network 504. The chipset 506 may include a memory control hub (MCH) 508. The MCH 508 may include a memory controller 510 that communicates with a memory 512. The memory 512 may store data, including sequences of instructions, that are executed by the CPU 502, or any other device included in the computing system 500. For example, operations may be coded into instructions (e.g., stored in the memory 512) and executed by processor(s) 502. In one embodiment of the invention, the memory 512 may include one or more volatile storage (or memory) devices such as random access memory (RAM), dynamic RAM (DRAM), synchronous DRAM (SDRAM), static RAM (SRAM), or other types of storage devices. Nonvolatile memory may also be utilized such as a hard disk. Additional devices may communicate via the interconnection network 504, such as multiple CPUs and/or multiple system memories.

The MCH 508 may also include a graphics interface 514 that communicates with a display device 516. In one embodiment of the invention, the graphics interface 514 may communicate with the display device 516 via an accelerated graphics port (AGP). In an embodiment of the invention, the display 516 (such as a flat panel display) may communicate with the graphics interface 514 through, for example, a signal converter that translates a digital representation of an image stored in a storage device such as video memory or system memory into display signals that are interpreted and displayed by the display 516. The display signals produced by the display device may pass through various control devices before being interpreted by and subsequently displayed on the display 516.

A hub interface 518 may allow the MCH 508 and an input/output control hub (ICH) 520 to communicate. The ICH 520 may provide an interface to I/O device(s) that communicate with the computing system 500. The ICH 520 may communicate with a bus 522 through a peripheral bridge (or controller) 524, such as a peripheral component interconnect (PCI) bridge, a universal serial bus (USB) controller, or other types of peripheral bridges or controllers. The bridge 524 may provide a data path between the CPU 502 and peripheral devices. Other types of topologies may be utilized. Also, multiple buses may communicate with the ICH 520, e.g., through multiple bridges or controllers. Moreover, other peripherals in communication with the ICH 520 may include, in various embodiments of the invention, integrated drive electronics (IDE) or small computer system interface (SCSI) hard drive(s), USB port(s), a keyboard, a mouse, parallel port(s), serial port(s), floppy disk drive(s), digital output support (e.g., digital video interface (DVI)), or other devices.

The bus 522 may communicate with an audio device 526, one or more disk drive(s) 528, and a network interface device 530 (which is in communication with the computer network 503). Other devices may communicate via the bus 522. Also, various components (such as the network interface device 530) may communicate with the MCH 508 via a high speed (e.g., general purpose) I/O bus channel in some embodiments of the invention. In addition, the processor 502 and other components shown in FIG. 5 (including but not limited to the MCH 508, one or more components of the MCH 508, etc.) may be combined to form a single chip. Furthermore, a graphics accelerator may be included within the MCH 508 in other embodiments of the invention.

Furthermore, the computing system 500 may include volatile and/or nonvolatile memory (or storage). For example, nonvolatile memory may include one or more of the following: read-only memory (ROM), programmable ROM (PROM), erasable PROM (EPROM), electrically EPROM (EEPROM), a disk drive (e.g., 528), a floppy disk, a compact disk ROM (CD-ROM), a digital versatile disk (DVD), flash memory, a magneto-optical disk, or other types of nonvolatile machine-readable media that are capable of storing electronic data (e.g., including instructions). In an embodiment, components of the system 500 may be arranged in a point-to-point (PtP) configuration. For example, processors, memory, and/or input/output devices may be interconnected by a number of point-to-point interfaces.

Reference in the specification to “one embodiment,” “an embodiment,” or “some embodiments” means that a particular feature, structure, or characteristic described in connection with the embodiment(s) may be included in at least an implementation. The appearances of the phrase “in one embodiment” in various places in the specification may or may not be all referring to the same embodiment.

Also, in the description and claims, the terms “coupled” and “connected,” along with their derivatives, may be used. In some embodiments of the invention, “connected” may be used to indicate that two or more elements are in direct physical or electrical contact with each other. “Coupled” may mean that two or more elements are in direct physical or electrical contact. However, “coupled” may also mean that two or more elements may not be in direct contact with each other, but may still cooperate or interact with each other.

Thus, although embodiments of the invention have been described in language specific to structural features and/or methodological acts, it is to be understood that claimed subject matter may not be limited to the specific features or acts described. Rather, the specific features and acts are disclosed as sample forms of implementing the claimed subject matter.

1. An integrated circuit comprising:
a first transistor coupled between a second transistor and a third transistor, wherein the second transistor is coupled to a word line and the third transistor is coupled to a data storage element;
a logic to couple the first transistor to a fixed voltage in response to a first value of a voltage supply and to drive the first transistor in accordance with a control word line in response to a second value of the voltage supply,
wherein the first value has a higher value than the second value.

2. The integrated circuit of claim 1, wherein the data storage element comprises a plurality of cross-coupled inverters.

3. The integrated circuit of claim 1, wherein the second transistor is coupled to a bit line.

4. The integrated circuit of claim 3, wherein the first, second, and third transistors are to pull down the bit line.

5. The integrated circuit of claim 3, further comprising a plurality of pull-up transistors coupled to the bit line.

6. The integrated circuit of claim 5, wherein at least one of the plurality of pull-up transistors is driven by an inverted version of the bit line.

7. The integrated circuit of claim 1, further comprising a line driver to drive the control word line based on the word line and a control signal.

8. The integrated circuit of claim 1, further comprising a fourth transistor coupled to the first and second transistors and a voltage supply to reduce pull-down leakage in the integrated circuit.

9. A processor comprising:
a processing core; and
a register file to store one or more bits of data, the register file to comprise:
a first transistor coupled between a second transistor and a third transistor, wherein the second transistor is coupled to a word line and the third transistor is coupled to a data storage element;
a logic to couple the first transistor to a fixed voltage in response to a first value of a voltage supply and to drive the first transistor in response to a second value of the voltage supply, wherein the first value has a higher value than the second value.

10. The processor of claim 9, further comprising a line driver to drive a control word line based on the word line and a control signal, wherein the logic is to drive the first transistor in accordance with the control word line in response to the second value of the voltage supply.

11. The processor of claim 9, further comprising a fourth transistor coupled to the first and second transistors and a voltage supply to reduce pull-down leakage in the register file.

12. The processor of claim 9, wherein the second transistor is coupled to a bit line.

13. The processor of claim 12, wherein the first, second, and third transistors are to pull down the bit line.

14. The processor of claim 9, wherein the data storage element comprises a plurality of cross-coupled inverters.

15. The processor of claim 9, further comprising a plurality of processor cores.
